(19) United States
(12) Patent Application Publication
(10) Pub. No.: US 2009/0039513 A1
(43) Pub. Date: Feb. 12, 2009

(54) Contacting Method for Semiconductor Material and Semiconductor Device

(75) Inventors: Peter Fath, Konstanz (DE); Ihor Melnyk, Konstanz (DE)

Correspondence Address: LERNER GREENBERG STEMER LLP, P O BOX 2480, HOLLYWOOD, FL, 33022-2480, US

(73) Assignee: GP SOLAR GMBH, Konstanz (DE)

(21) Appl. No.: 12/235,264

(22) Filed: Sep. 22, 2008

Related U.S. Application Data
(63) Continuation of application No. PCT/EP2007/001636, filed on Feb. 26, 2007.

(30) Foreign Application Priority Data
Mar. 21, 2006 (DE) 10 2006 013 336.6

(51) Int. Cl. H01L 23/52; H01L 21/44

(52) U.S. Cl. 257/751; 438/653; 257/E21.584

(57) ABSTRACT

A contact-making method for a semiconductor material contains the method steps of forming a diffusion barrier which promotes electrical contact and adhesion on at least one portion of a surface of a semiconductor and forming a metallization on the diffusion barrier. The diffusion barrier being formed by applying a metalliforous paste to at least one portion of the semiconductor surface or to at least one portion of a layer covering the semiconductor surface, and a semiconductor component with a diffusion barrier which is arranged in the surface of the semiconductor and which promotes electrical contact between the semiconductor material and a metallization. The metallization is applied to the diffusion barrier. The diffusion barrier is formed by a sintered metalliforous paste applied to at least one portion of the semiconductor surface.

### CROSS-REFERENCE TO RELATED APPLICATION

This is a continuing application, under 35 U.S.C. § 120, of copending international application No. PCT/EP2007/001636, filed Feb. 26, 2007, which designated the United States; this application also claims the priority, under 35 U.S.C. § 119, of German patent application No. DE 10 2006 013 336.6, filed Mar. 21, 2006; the prior applications are herewith incorporated by reference in their entirety.

### BACKGROUND OF THE INVENTION

1. Field of the Invention

The invention relates to a contacting method for a semiconductor material by forming an electrically contacting and bonding diffusion barrier on at least part of the surface of the semiconductor material and forming a metallization on the diffusion barrier.

In the production of semiconductor devices, or at the latest when they are integrated in an electrical or electronic circuit, it is necessary to form an electrical contact between the semiconductor material and a metallic conductor. In particular, the production of solar cells requires the electrical contacting of the semiconductor material for the purpose of removing charge carriers generated in the semiconductor material. It is generally intended for the contacting to be permanently reliable, so it must bond to the semiconductor material. Moreover, it is intended for the material used to have an electrical conductivity that is as good as possible; on the one hand to involve the lowest possible requirement for material, on the other hand to need only little surface area for the forming of an electrical supply or discharge with sufficiently high electrical conductivity.

Electrical contacting methods of varying degrees of complexity are known. If there is no available metal that bonds adequately well to the semiconductor material used and at the same time has the required electrical conductivity, it is possible for example for a layer of a first metal, which bonds sufficiently on the semiconductor material, first to be vapor-deposited onto it. Then a further layer of a second metal, which bonds well on the first layer and has greatest possible electrical conductivity, is applied onto the first metal.

With vapor-deposited contacts, a high-quality contact can be realized with at the same time a low surface-area requirement, but its production is costly on account of the vacuum installations required. Moreover, in the case of silicon, as the most frequently used semiconductor material, the forming of a satisfactory contact requires materials that are rare, and consequently expensive, such as titanium and palladium in conjunction with silver, which stands in the way of large quantities being used.

In addition, in many cases the range of usable metals is restricted by the requirement that they must not have any harmful influence on the respectively used properties of the semiconductor material. Therefore, the use of some materials is ruled out in many cases, since, in a subsequent thermal treatment, they diffuse too quickly into the volume of a semiconductor material, where they form for example recombination centers for charge carriers, which in turn adversely affects the function of the device produced from it.

Furthermore, it is known, inter alia, to contact semiconductor materials by applying and sintering in metal-containing pastes or the like. In particular in the area of solar cell production, there have been developed for this purpose pastes which are applied onto semiconductor materials by printing techniques, such as screen or stamp printing, and after thermal treatment that is often referred to as sintering or contact sintering form an ohmic contact with respect to the semiconductor material. Silver and/or aluminum are often used in this case as metals.

With such methods it is possible to carry out comparatively low-cost contacting of semiconductor materials. However, the surface area requirement is comparatively great. For example in the case of solar cells, this has the effect of reducing the semiconductor area that is available for power generation. This is not necessarily caused by the printing techniques that are used requiring certain minimum dimensioning, but in many cases by the fact that the pastes used can only be applied in a controlled manner up to a certain thickness by a printing operation. However, thickening by multiple printing makes it already necessary to position and align the printing device that is used, such as a screen or stamp, and the semiconductor material that has already been printed.

Moreover, additional thermal treatments between the individual printing operations are required to stabilize the layers already printed, which moreover can contribute to deterioration of the material properties. For example, this may lead to increased diffusion of impurities into the volume of the semiconductor material, which in turn can adversely affect the properties of the semiconductor device produced, even to the extent that it is unusable.

### SUMMARY OF THE INVENTION

It is accordingly an object of the invention to provide a contacting method for a semiconductor material and a semiconductor device that overcome the above-mentioned disadvantages of the prior art methods and devices of this general type, by which reliable, low-cost contacting of semiconductor material can be realized with at the same time a lowest possible surface area requirement and a greatest possible electrical conductivity being achieved.

With the foregoing and other objects in view there is provided, in accordance with the invention, a method for contacting a semiconductor material. The method includes the steps of: forming an electrically contacting and bonding diffusion barrier on at least part of a surface of the semiconductor material by applying a metal-containing paste onto at least part of the surface of the semiconductor material or to at least part of a layer covering the surface of the semiconductor material; and forming a metallization on the diffusion barrier.

The method can be advantageously used for the contacting of semiconductor material of a semiconductor device, in particular a semiconductor device of silicon.

Furthermore, the invention is based on the problem of providing a semiconductor device containing a semiconductor material that can be contacted reliably and at low cost, the contacting of which has a low surface area requirement and at the same time high electrical conductivity.

The concept on which the invention is based is that of forming an electrically contacting and bonding diffusion barrier on at least part of the surface of a semiconductor by applying a metal-containing paste onto at least part of the semiconductor surface or to at least part of a layer covering the semiconductor surface and forming a metallization on the diffusion barrier. For the purposes of the present invention, a metal-containing paste is understood as meaning a paste which contains at least one pure metal and/or a metal alloy and/or a metal compound, in particular at least one metal oxide.

The diffusion barrier acts here as a bonding layer between the semiconductor material and the metallization and counteracts the diffusion of metals from the metallization into the semiconductor material and the possibly accompanying adverse effect on the properties of the semiconductor material and properties of the semiconductor device, so that metals available in large quantities can be increasingly used in spite of their characteristic of diffusing comparatively quickly in the semiconductor material used. At the same time, the use of metal-containing pastes makes it possible to apply these pastes by low-cost printing techniques. The metallization applied onto the diffusion barrier for its part makes it possible to obtain greatest possible electrical conductivity of the contacting.

In this way, a reliable, low-cost contacting of semiconductor material can be realized with at the same time low surface area requirement and great electrical conductivity, or a semiconductor device formed in such a way.

Other features which are considered as characteristic for the invention are set forth in the appended claims.

Although the invention is illustrated and described herein as embodied in a contacting method for a semiconductor material and a semiconductor device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a flow chart showing a first exemplary embodiment of a method according to the invention;

FIG. 2 is a flow chart showing a second exemplary embodiment of the method according to the invention;

FIG. 3 is a diagrammatic, sectional view of a first exemplary embodiment of a semiconductor device according to the invention;

FIG. 4 is a diagrammatic, sectional view of a second exemplary embodiment of the semiconductor device according to the invention; and

FIG. 5 is a diagrammatic, perspective view of a solar cell as a third exemplary embodiment of the semiconductor device according to the invention.

### DETAILED DESCRIPTION OF THE INVENTION

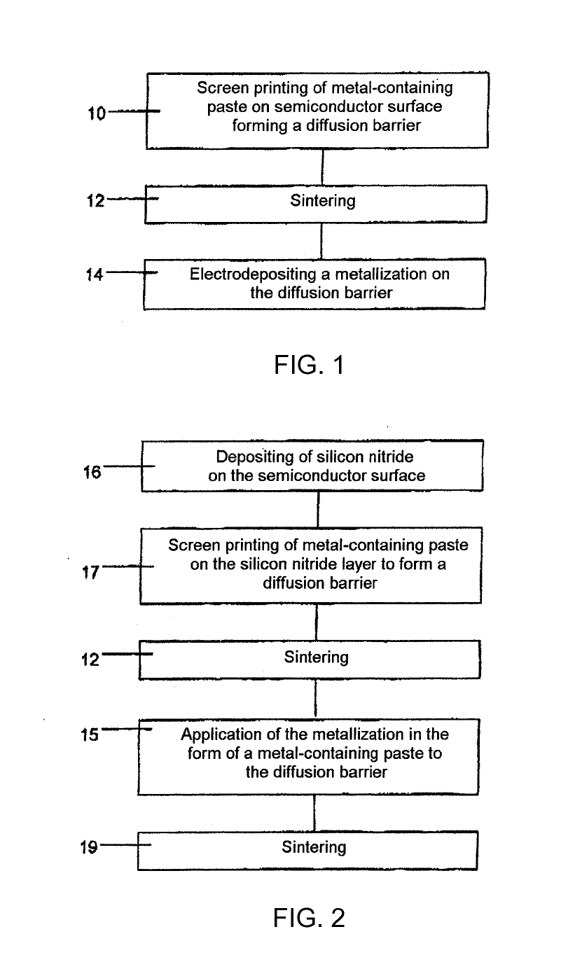

Referring now to the figures of the drawing in detail and first, particularly, to FIG. 1 thereof, there is shown a first exemplary embodiment of the method according to the invention. In the method, first a metal-containing paste is applied onto the surface of a semiconductor material by a screen printing technique, step 10. This is then alloyed into the semiconductor material in a thermal step, which is often referred to as sintering or contact sintering, step 12. In the process, the metal from the paste forms an ohmic contact together with the semiconductor material. In the case of silicon as the semiconductor material that is used, this may cause, for example, the formation of metal silicides. In addition, it goes without saying that all other elementary semiconductors, such as for example germanium or compound semiconductor materials such as, inter alia, gallium arsenide or copper indium diselenide, may be used as semiconductor materials.

The metal-containing paste and its constituents are in this case chosen such that they act as a diffusion barrier for the metallization subsequently applied. In the case of silicon as the semiconductor material used, pastes containing silver and/or nickel and/or molybdenum and/or palladium and/or chromium and/or aluminum may be used for this, for example, it being possible for the materials mentioned also in each case to take the form of an alloy or a compound. Once they have been alloyed in, there forms a layer that acts as a diffusion barrier, in particular for a metallization containing silver and/or tin and/or copper. The use of copper is particularly advantageous for this, since it is available in large quantities, whereas silver is much more rare.

As a result of the diffusion barrier that is formed, in the example mentioned the stated materials can be deposited on the diffusion barrier in a subsequent electrodepositing operation 14, without a relevant risk of degradation of the semiconductor material existing as a result of diffusion of the deposited materials into the semiconductor material. The materials used for the metallization and the diffusion barrier must in this case obviously be made to suit one another. The materials stated for the case where silicon is used as the semiconductor material may, however, also be used in the case of the other materials that are common in semiconductor technology. Instead of electrodepositing, it is also possible to use electroless depositing technology or plating technology, known per se. If a number of different materials are deposited, it is possible moreover to provide a combination of different depositing technologies.

FIG. 2 shows a further exemplary embodiment of the method according to the invention. In it, silicon nitride is first deposited as a dielectric layer on the surface of the semiconductor material, step 16, before application, step 17, of the metal-containing paste onto the silicon nitride layer is performed by screen printing. The use of a screen printing technique is not absolutely necessary here. Alternatively, other techniques for applying the paste, in particular screen printing, spray printing, web printing, stencil printing or stamp printing, may obviously be used in all the embodiments. Application of the metal-containing paste is followed by the sintering step 12, already known from the exemplary embodiment of FIG. 1.

Following this, the metallization in the exemplary embodiment of FIG. 2 is applied onto the diffusion barrier in the form of a further metal-containing paste 15. This may in turn be performed, for example, by a printing technique, in particular by screen printing. In addition, however, all other printing processes of the known methods of paste application are also conceivable in particular. In the exemplary embodiment of FIG. 2, in a subsequent step the further metal-containing paste is sintered, step 19, in order in this way to drive out solvent and form an ohmic contact between the diffusion barrier and the metallization.

In addition, however, there is also the possibility of combining the sintering operations, steps 12 and 19, in one sintering step. In this case, there is no sintering operation after the screen printing of the metal-containing paste onto the dielectric layer, in the present case the silicon nitride layer. Instead, the metal-containing paste is applied for the metallization. The forming of an ohmic contact between the semiconductor material and the diffusion barrier and also between the diffusion barrier and the metallization is then performed in a common, subsequent sintering step.

It is also conceivable in the exemplary embodiment of FIG. 1 to form the metallization by applying a metal-containing paste. As already stated at the beginning, an exact alignment of the semiconductor material and of the device used for the paste application, for example the screen of a screen printing device, is necessary here. Otherwise, some of the further metal-containing paste for the metallization will be applied alongside the diffusion barrier directly onto the semiconductor surface, from where it can diffuse unhindered into the volume of the semiconductor material and adversely affect the properties thereof, in particular in a thermal treatment of the semiconductor material. In many cases, it may therefore be expedient not to provide full-area application of the metallization onto the diffusion barrier but to make the surface-area extent of the metallization smaller than that of the diffusion barrier. As a result, with optimum application of the metallization, the diffusion barrier protrudes out from under the latter. There is then a tolerance range, which, given a limited inaccuracy of the positioning of the metallization on the diffusion barrier, prevents direct contact of the paste with the surface of the semiconductor material.

If a dielectric layer is first applied onto the semiconductor area, as in the case of the exemplary embodiment of FIG. 2, inaccurate alignment of the metallization, or a metallization protruding beyond the diffusion barrier, is uncritical, since it does not come into contact directly with the surface of the semiconductor material but with the dielectric layer, which prevents the diffusion of impurities into the semiconductor material. This is illustrated by the exemplary embodiment that is schematically represented in FIG. 4 and explained in more detail further below of a semiconductor device according to the invention, a metallization 34 of which protrudes beyond the surface-area extent of a diffusion barrier 32 and partially covers a adjacent dielectric layer 31.

The described configuration of the metallization may also be used for the purpose of increasing the electrical conductivity in the contacting formed by the diffusion barrier and the metallization by increasing the conducting cross section, by a metallization that protrudes at least partially beyond the dimensions of the diffusion barrier.

The exemplary embodiments described and the method according to the invention itself can be advantageously used for the contacting of solar cells, in particular the sides thereof that are facing the light. In addition, they can be used in the case of all semiconductor devices in which a semiconductor material is to be contacted in an electrically conducting manner.

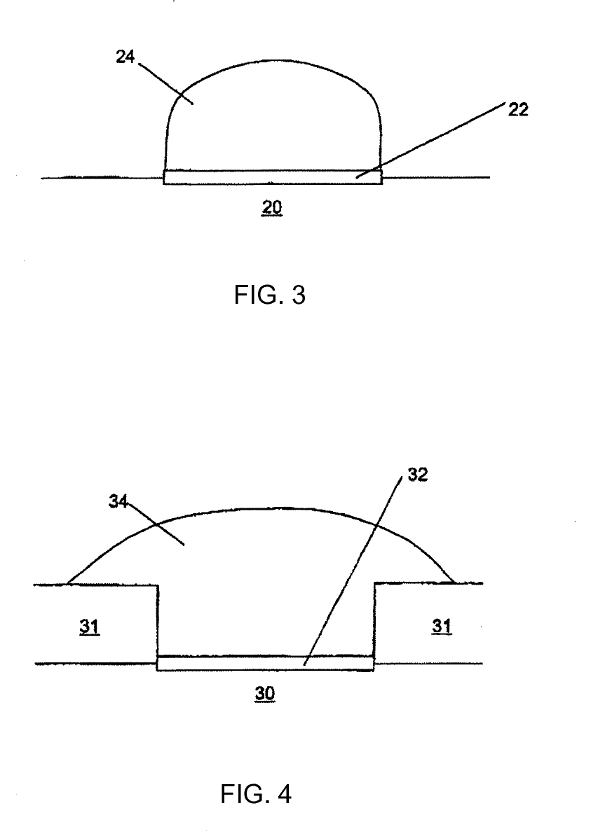

FIG. 3 schematically shows in a sectional representation a first exemplary embodiment of a semiconductor device according to the invention, which has electrically conducting contacting of a semiconductor material 20. Arranged in the surface of the semiconductor material 20 is a diffusion barrier 22, on which a metallization 24 is provided. The diffusion barrier 22 thereby provides an electrically conducting contact between the semiconductor material 20 and the metallization 24. Moreover, the diffusion barrier 22 is formed by a metal-containing paste applied onto at least part of the semiconductor surface and sintered in.

In the exemplary embodiment of FIG. 3, the metallization 24 may be formed, for example, by electrodepositing of metal or a metal alloy, in particular silver or copper.

The semiconductor device could have been produced, for example, by the method from exemplary embodiment 1.

FIG. 4 shows a further exemplary embodiment of the semiconductor device according to the invention. By contrast with the exemplary embodiment from FIG. 3, here the dielectric layer 31 is provided adjacent the diffusion barrier 32. The diffusion barrier 32 as well as the dielectric layer 31 are arranged on the surface of a semiconductor material 30. As already described in connection with the method according to the invention, any elementary semiconductor or compound semiconductor may be concerned here.

A metallization 34 is again arranged on the diffusion barrier 32. In the exemplary embodiment of FIG. 4, the metallization extends beyond the surface-area extent of the diffusion barrier 32 and at least partially covers the adjacent dielectric layer 31. As already explained in connection with the exemplary embodiment of the method according to the invention from FIG. 2, this is of advantage in particular whenever the metallization is applied in the form of a metal-containing paste, since alignment errors or tolerances cannot lead to paste getting onto the surface of the semiconductor material and being able to diffuse from there into the volume of the semiconductor material. The metallization 34 is therefore preferably formed from metal-containing and sintered paste.

Nevertheless, a semiconductor device in which the metallization partially covers the dielectric layer in a way corresponding to the exemplary embodiment from FIG. 4 may also be realized by other ways of forming the metallization. For example, it may have been applied by electrodepositing or by an electroless depositing or coating technology. A combination of different depositing technologies is also conceivable.

The exemplary embodiments of semiconductor devices according to the invention of FIGS. 3 and 4 may be considered on the one hand as semiconductor devices in the sense of a metal-semiconductor contact or as details of other semiconductor devices known per se, such as for example diodes, transistors, thyristors, microprocessors, sensors, microswitches, solar cells, detectors and the like, in which a semiconductor material has the respectively represented electrical contact.

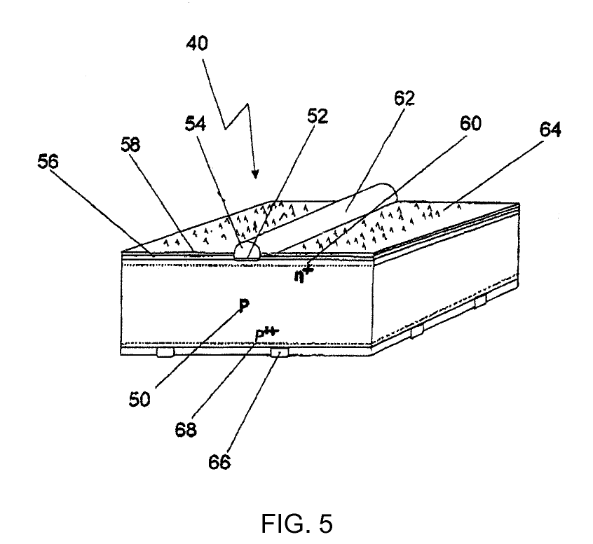

FIG. 5 shows a schematic representation of a solar cell 40 as a semiconductor device, fingers 62 of a front metallization of which are formed according to the invention, and for which FIG. 4 consequently represents the drawing of a detail, if a first dielectric layer 56 and a second dielectric layer 58 of the solar cell are considered to be a dielectric layer 31 in the sense of FIG. 4.

The solar cell 40 in FIG. 5 is a p-type solar cell with a p-doped semiconductor material 50 as the starting material, in particular with p-doped silicon as the starting material. However, the contacting according to the invention can also be used in the same way for n-type solar cells or n-doped semiconductor materials.

The fingers 62 of the front metallization are formed according to the invention and have a diffusion barrier 52, which is formed from a metal-containing and sintered-in paste. A metallization 54, which in the present case is formed by electrodepositing a metal, preferably silver or copper, has been applied onto the diffusion barrier 52. However, as described above, the metallization 54 may also be applied in some other way.

Formed on the upper side of the solar cell 40 in a way known per se is an n-doped emitter 60. The emitter 60 is particularly sensitive to the ingress of impurities from the metallization, since on the one hand this may cause conducting connections through the emitter 60 that short-circuit the solar cell, and greatly reduce the conversion efficiency of the solar cell 40, and on the other hand such impurities may represent recombination centers for the charge carriers generated in the volume of the semiconductor material 50, which in turn leads to a reduced current yield. The risk of these adverse effects is all the greater the faster impurities, in particular metals, diffuse from the metallization in the semiconductor material 50 that is used, which is of significance in particular in thermal treatments of the solar cell 40 during its production.

However, according to the invention, the diffusion of impurities from the metallization 54 into the volume of the semiconductor material of the solar cell 40 is hindered or even prevented by the applied diffusion barrier 52. As a consequence, commonly occurring metals such as copper and/or nickel or alloys of these materials may be used for example for the metallization 54 of a silicon solar cell 40, without this causing any adverse effect on efficiency in subsequent thermal treatment of the solar cell 40.

In the exemplary embodiment of FIG. 5, a back surface field 68, which is formed by stronger p doping in comparison with the volume of the semiconductor material (in the case of n-type solar cells correspondingly stronger n doping) is provided on the back side of the solar cell. The back surface field 68 reduces the recombination of generated charge carriers, and thereby increases the conversion efficiency of the solar cell 40. In principle, it is also possible to dispense with the formation of a full-area back surface field or to provide it only locally.

The contacting of the back side of the solar cell, i.e. in effect of the volume of the semiconductor material 50, takes place using back-side contacts 66, if appropriate by way of the back surface field 68 represented in FIG. 5. In the exemplary embodiment of FIG. 5, the back-side contacts 66 of the solar cell 40 are not formed according to the invention. Here, no diffusion barrier has been provided between the semiconductor material 50 and the metallization of the back-side contacts 66. Accordingly, suitable materials must be used and thermal treatment of the solar cell 40 during production must be performed at lowest possible temperatures after application of the back-side contacts. In principle, however, the back-side contacts 66 can likewise be readily formed according to the invention with a diffusion barrier.

This is of advantage in particular whenever, for production reasons, the type of solar cell that is produced is exposed to high temperatures after application of the back-side metallization.

A width in a range from 10 to 100 μm has proven to be favorable for the width of the fingers of the front metallization 62. With preference, the width lies in a range from 30 to 70 μm and, with particular preference, is 30 μm. In this way, least possible shading of the active surface of the solar cell 40 with regard to power generation is achieved. The electrical conductivity of the fingers 62 that is necessary for the current to be optimally led away is in this case ensured by the choice of a material for the metallization 54 that has the best possible electrical conduction and choice of a corresponding cross section of the fingers 62. With a reduced finger width, the required finger cross section is compensated by a thicker metallization 54 in the direction normal to the surface of the solar cell 40, and consequently an increased finger thickness.

In the exemplary embodiment of FIG. 5, to obtain a further increase in efficiency of the solar cell 40, the latter is also provided with a surface texturing 64 on its front side. This may in particular have been chemically or mechanically applied in a way known per se. This illustrates that the form of semiconductor devices according to the invention, in particular solar cells, and the use of the method according to the invention are not restricted to semiconductor devices with an even semiconductor surface. Rather, comparatively uneven semiconductor surfaces may also be provided with an electrical contact according to the invention, which is advantageous in particular in the case of solar cells of novel materials such as for example types of silicon ribbon, which generally does not have an even surface. This is made possible by the way in which the diffusion barrier is formed according to the invention by applying the metal-containing paste, which can be realized with a comparatively high tolerance with respect to irregularities of the surface of the semiconductor material.

1. A method for contacting a semiconductor material, which comprises the steps of:
forming an electrically contacting and bonding diffusion barrier on at least part of a surface of the semiconductor material by applying a metal-containing paste onto at least part of the surface of the semiconductor material or to at least part of a layer covering the surface of the semiconductor material; and
forming a metallization on the diffusion barrier.

2. The method according to claim 1, which further comprises applying the metal-containing paste via a printing technique.

3. The method according to claim 1, which further comprises following the applying of the metal-containing paste with the step of contact sintering carried out at temperatures in a range from 300° C. to 900° C.

4. The method according to claim 1, which further comprises forming the layer covering the surface of the semiconductor material as at least one dielectric layer on at least part of the surface of the semiconductor material.

5. The method according to claim 4, which further comprises depositing one of an oxide layer and a nitride layer as the dielectric layer.

6. The method according to claim 1, which further comprises forming the metal-containing paste to contain at least one of silver, nickel, palladium, molybdenum, chromium, aluminum, an alloy having one of these elements, and a compound of one of these elements.

7. The method according to claim 1, which further comprises forming the metallization on the diffusion barrier by overprinting the diffusion barrier with a second metal-containing paste.

8. The method according to claim 1, which further comprises forming the metallization on the diffusion barrier by one of electrodepositing and electroless depositing of at least of one metal and at least one metal alloy.

9. The method according to claim 4, which further comprises applying the metallization onto the diffusion barrier such that the metallization extends beyond the diffusion barrier and covers at least parts of the dielectric layer, that is adjacent the diffusion barrier and at least partially covers the surface of the semiconductor material.

10. The method according to claim 2, which further comprises selecting the printing technique from the group consisting of screen printing, spray printing, web printing, stencil printing and stamp printing.

11. The method according to claim 3, which further comprises setting the temperatures in the range from 500° C. to 900° C.

12. The according to claim 5, which further comprises:
providing the oxide layer as a silicon oxide layer; and
providing the nitride layer as a silicon nitride layer.

13. The method according to claim 7, which further comprises forming the second metal-containing paste as a paste containing at least one of silver, aluminum, and copper and performing the overprinting by one of screen printing, spray printing, web printing, stencil printing and stamp printing.

14. The method according to claim 8, which further comprises selecting the metal from the group consisting of silver and copper.

15. A method for contacting a semiconductor material of a semiconductor device, which comprises the steps of:
forming an electrically contacting and bonding diffusion barrier on at least part of a surface of the semiconductor material by applying a metal-containing paste onto at least part of the surface of the semiconductor material or to at least part of a layer covering the surface of the semiconductor material; and
forming a metallization on the diffusion barrier.

16. The method according to claim 15, which further comprises forming the semiconductor device from silicon.

17. The method according to claim 15, which further comprises:
forming the semiconductor device as a solar cell; and
contacting at least one of a front side and a back side of the solar cell.

18. A semiconductor device, comprising:
a semiconductor material having a surface;
a metallization; and
a diffusion barrier disposed on said surface of said semiconductor material and providing electrical contact between said semiconductor material and said metallization, said metallization applied onto said diffusion barrier, said diffusion barrier formed by a metal-containing paste applied onto at least part of said surface of said semiconductor material and sintered in.

19. The semiconductor device according to claim 18, wherein said metal-containing paste is applied by a printing technique.

20. The semiconductor device according to claim 21, wherein said diffusion barrier contains at least one combination of:
silver, compounds of silver, and said semiconductor material;
nickel, compounds of nickel and said semiconductor material;
palladium, compounds of palladium and said semiconductor material;
molybdenum, compounds of molybdenum and said semiconductor material;
chromium, compounds of chromium and said semiconductor material;
aluminum, compounds of aluminum and said semiconductor material; and
an alloy of one of these elements mentioned, a compound of said alloy and said semiconductor material.

21. The semiconductor device according to claim 18, further comprising at least one dielectric layer disposed on said surface of said semiconductor material and is at least partially adjacent said diffusion barrier.

22. The semiconductor device according to claim 21, wherein said dielectric layer is formed as one of an oxide layer and a nitride layer.

23. The semiconductor device according to claim 21, wherein said metallization covers at least part of said dielectric layer adjacent said diffusion barrier.

24. The semiconductor device according to claim 18, wherein said metallization is formed from a metal-containing and sintered paste.

25. The semiconductor device according to claim 18, wherein applying one of a metal and a metal alloy as said metallization.

26. The semiconductor device according to claim 18, wherein the semiconductor device is a solar cell.

27. The semiconductor device according to claim 26, wherein said metallization has a front with fingers of the solar cell and are at least partially formed by said diffusion barrier and said metallization applied thereon.

28. The semiconductor according to claim 26, further comprising back-side contacts of the solar cell being at least partly formed by said diffusion barrier and said metallization applied thereon.

29. The semiconductor device according to claim 27, wherein said fingers have a width of between 10 and 100 μm.

30. The semiconductor device according to claim 19, wherein said printing technique is selected from the group containing screen printing, spray printing, web printing, stencil printing and stamp printing.

31. The semiconductor device according to claim 21, wherein said dielectric layer surrounds said diffusion barrier.

32. The semiconductor device according to claim 21, wherein said dielectric layer is formed by one of a silicon oxide and a silicon nitride layer.

33. The semiconductor device according to claim 24, wherein said metal-containing and sintered paste contains at least one of silver, aluminum, and copper

34. The semiconductor device according to claim 25, wherein said metal is selected from the group consisting of silver and copper.

35. The semiconductor device according to claim 29, wherein said width is between 30 and 70 μm.

36. The semiconductor device according to claim 29, wherein said width is between 30 μm.
